(19) United States
(12) Patent Application Publication
(10) Pub. No.: US 2024/0125857 A1
(43) Pub. Date: Apr. 18, 2024

(54) METHOD FOR CALCULATING STATE OF CHARGE OF BATTERY

(71) Applicants: Shanghai Makesens Energy Storage Technology Co., Ltd., Shanghai (CN); Shanghai Volta Institute of Digital Battery Energy Storage, Shanghai (CN)

(72) Inventors: Zonglin CAI, Shanghai (CN); Peng DING, Shanghai (CN); Guopeng ZHOU, Shanghai (CN); Enhai ZHAO, Shanghai (CN); Xiao YAN, Shanghai (CN)

(73) Assignees: Shanghai Makesens Energy Storage Technology Co., Ltd., Shanghai (CN); Shanghai Volta Institute of Digital Battery Energy Storage, Shanghai (CN)

(21) Appl. No.: 18/474,308

(22) Filed: Sep. 26, 2023

(30) Foreign Application Priority Data
Oct. 18, 2022 (CN) 202211272834.9

(51) Int. Cl. G01R 31/367; G01R 31/378; G01R 31/382

(52) U.S. Cl. CPC G01R 31/367; G01R 31/378; G01R 31/382

(57) ABSTRACT

A method for calculating a state of charge of a battery is provided. The method includes: estimating a first state of charge of the battery by using a first state of charge estimation algorithm; estimating a second state of charge of the battery by using a second state of charge estimation algorithm; determining a first weight corresponding to the first state of charge and a second weight corresponding to the second state of charge based on state data of the battery; and calculating the state of charge of the battery based on the first state of charge and the first weight, and the second state of charge and the second weight. With method for calculating a state of charge of a battery in the present disclosure, the accuracy of calculating the state of charge of the battery can be improve d with a lower computation cost.

### CROSS-REFERENCE TO RELATED APPLICATION

This application claims priority to Chinese Patent Application No. 202211272834.9, filed on Oct. 18, 2022, which is incorporated herein by its reference in its entirety.

### TECHNICAL FIELD

The present disclosure relates to the technical field of batteries, and in particular to a method for calculating a state of charge of a battery with high accuracy at a low computational cost based on different algorithms for estimating a state of charge.

### BACKGROUND

In a management system of a battery that serves as an energy storage device, a state of charge (SOC) of the battery is a core state, which affects a state of health (SOH) of the battery, a state of energy (SOE) of the battery, a state of power (SOP) of the battery, and even safety of the battery. However, due to the complex environment in which the battery operates and multiple influencing parameters, it is difficult to accurately predict the state of charge of the battery.

For example, in process of charging and discharging a Lithium iron phosphate battery, when the charging and discharging process stops and the direction of the current changes, an internal balance of the battery changes, and an ohmic internal resistance, an electrochemical polarization state and a concentration polarization state of the battery changes, causing a rapid change in the voltage of the battery in the charging and discharging process, and requiring a long time to restore to a balanced state. In the above process, the change of the voltage may cause significant errors in calculating the state of charge of the battery based on battery parameters such as the voltage and the current. In addition, due to that the concentration polarization process requires a long time period and concentration polarization parameters are different in different states of charge, the calculated state of charge fluctuates in the longer time period. Therefore, during the time period from the charging and discharging process of the battery stops to the battery reaching a new balanced state, a measured terminal voltage of the battery cannot be determined as an open circuit voltage of the battery.

The above changes mainly occur when the current of the battery undergoes a sudden change, that is, the direction of the current suddenly changes from positive to negative or from negative to positive, or the current changes from zero to present or from present to zero. In a case that the battery is charged with a constant current, the above changes occur less frequently or occur at the beginning or end of charging. In a case that the battery is charged with a frequency modulated current, the above changes occur frequently and has a significant impact.

Due to the above reasons, it is difficult to accurately estimate the state of charge of a battery when the current of the battery undergoes a sudden change.

### SUMMARY

In order to solve the above problems in the conventional technology, a method for calculating a state of charge of a battery is provided according to the present disclosure.

In the method for calculating a state of charge of a battery according to the present disclosure, the state of charge of the battery after an internal balance of the battery is broken is corrected based on measured state data of the battery in an internal change process, and the state of charge of the battery, in a time period from the internal balance of the battery is broken to the battery restores to a balanced state, is mathematically calculated based on different algorithms for estimating a state of charge of a battery.

A brief overview of the present disclosure is provided below to provide a basic understanding of some aspects of the present disclosure. It should be understood that this overview is not an exhaustive overview of the present disclosure, is not intended to determine key or important parts of the present disclosure or limit the scope of the present disclosure. The overview is provided to provide certain concepts in a simplified form as a prelude to a more detailed description to be discussed later.

In order to achieve the above purpose of the present disclosure, a method for calculating a state of charge of a battery is provided according to an aspect of the present disclosure. The method includes: estimating a first state of charge of the battery by using a first state of charge estimation algorithm; estimating a second state of charge of the battery by using a second state of charge estimation algorithm; determining a first weight corresponding to the first state of charge and a second weight corresponding to the second state of charge based on state data of the battery; and calculating the state of charge of the battery based on the first state of charge and the first weight, and the second state of charge and the second weight.

According to an embodiment of the present disclosure, the first state of charge estimation algorithm is an open circuit voltage algorithm, and the second state of charge estimation algorithm is an ampere hour integration algorithm.

According to an embodiment of the present disclosure, the first state of charge estimation algorithm is a battery equivalent circuit model-based algorithm based on at least one of an R-int equivalent circuit model of the battery, a first-order RC equivalent circuit model of the battery, and a second-order RC equivalent circuit model of the battery.

According to an embodiment of the present disclosure, the estimating a first state of charge of the battery by using a first state of charge estimation algorithm includes: establishing a state of charge model of the battery based on historical charging and discharging data of the battery; sensing current charging and discharging data of the battery; and estimating the first state of charge by using the state of charge model based on the current charging and discharging data.

According to an embodiment of the present disclosure, the state of charge model is a charging and discharging curve fitted based on the historical charging and discharging data or a lookup table formed based on the historical charging and discharging data.

According to an embodiment of the present disclosure, the historical charging and discharging data and the current charging and discharging data include a current and/or a voltage of the battery.

According to an embodiment of the present disclosure, the determining a first weight corresponding to the first state of charge and a second weight corresponding to the second state of charge based on state data of the battery includes: determining a current state of the battery based on the historical charging and discharging data and the current charging and discharging data; and determining the first weight and the second weight based on the current state.

According to an embodiment of the present disclosure, the determining a current state includes: determining whether the battery enters a hysteresis state; and in a case that the battery enters the hysteresis state, determining a time period in which the battery operates in the hysteresis state.

According to an embodiment of the present disclosure, the determining the first weight and the second weight based on the current state includes: in the case that the battery enters the hysteresis state, reducing the first weight and/or increasing the second weight; and gradually adjusting the first weight and/or increasing the second weight based on the time period in which the battery operates in the hysteresis state.

According to an embodiment of the present disclosure, the battery is a lithium ion battery or a Sodium-ion battery.

With the method for calculating a state of charge of a battery according to the present disclosure, the accuracy of calculating a state of charge of a battery can be improved at a small computational cost.

### BRIEF DESCRIPTION OF THE DRAWINGS

Referring to the descriptions of the embodiments of the present disclosure in conjunction with the accompanying drawings below, it is easy to understand the above and other purposes, features, and advantages of the present disclosure.

FIG. 1 shows a flow chart of a method for calculating a state of charge of a battery according to an embodiment of the present disclosure;

FIG. 2 shows a circuit diagram of an R-int equivalent circuit model of a battery;

FIG. 3 shows a circuit diagram of a first-order RC equivalent circuit model of a battery;

FIG. 4 shows a circuit diagram of a second-order RC equivalent circuit model of a battery; and

FIG. 5 shows a flow chart of an example of a method for calculating a state of charge of a battery according to an embodiment of the present disclosure.

### DETAILED DESCRIPTION OF THE EMBODIMENTS

In the following descriptions, some embodiments of the present disclosure are described in detail with reference to the accompanying explanatory diagrams. Reference numerals are used to indicate elements in the drawings. Although the same elements are shown in different drawings, the same elements are represented by the same reference numerals. In addition, in the following descriptions of the present disclosure, detailed descriptions of the known functions and configurations incorporated herein are omitted in cases where the subject matter of the present disclosure may be unclear.

The terms in this specification are only used for describing specific embodiments and are not intended to limit the present disclosure. As used in this specification, unless the context otherwise indicates, the singular form is intended to include the plural form. It should be understood that the terms “including”, “comprising”, and “having” used in the specification are intended to specifically describe the existence of the stated features, entities, operations, and/or components, but do not exclude the existence or addition of one or more other features, entities, operations, and/or components.

Unless otherwise defined, all terms, including terms technical and scientific terms, used in this specification have the same meanings as those commonly understood by those skilled in the art to which the present disclosure belongs. It should be further understood that terms such as those defined in commonly used dictionaries should be interpreted as having meanings consistent with their meanings in the context of the relevant field, and should not be interpreted in an idealized or overly formal sense unless explicitly defined herein.

In the following description, many specific details are described to provide a comprehensive understanding of the present disclosure. The present disclosure may be implemented without some or all of these specific details. In other embodiments, in order to avoid blurring the present disclosure due to unnecessary details, only components closely related to the solutions according to the present disclosure are shown in the accompanying drawings, while other details that are not closely related to the present disclosure are omitted.

Hereinafter, a method for calculating a state of charge of a battery according to an embodiment of the present disclosure is described in detail with reference to the accompanying drawings.

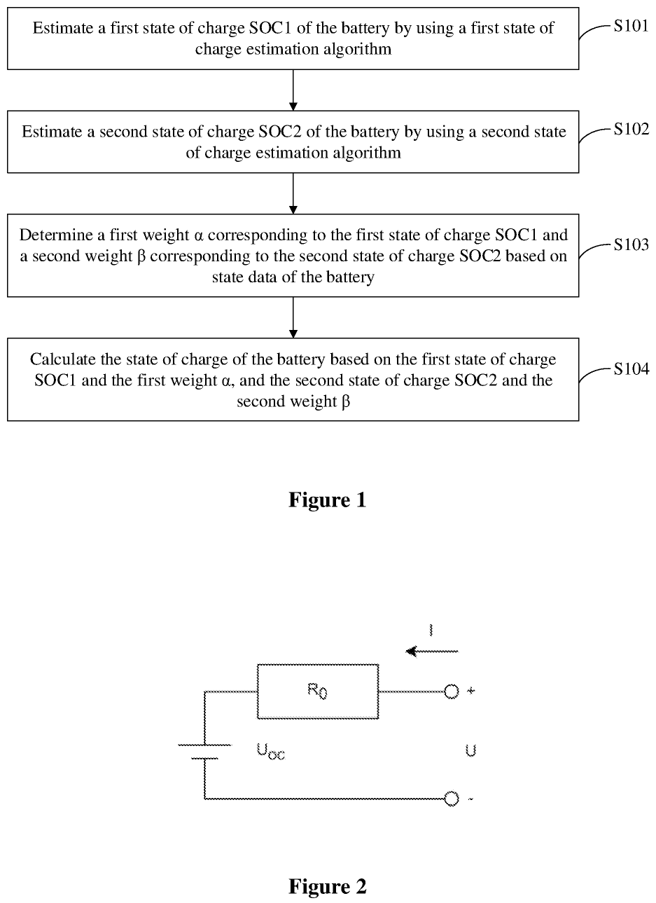

FIG. 1 shows a flow chart of a method 100 for calculating a state of charge of a battery according to an embodiment of the present disclosure. According to an embodiment of the present disclosure, the battery may be a lithium ion battery or a Sodium-ion battery. According to an embodiment of the present disclosure, the battery may be a Lithium iron phosphate battery.

As shown in FIG. 1, the method 100 according to the embodiment of the present disclosure may include the following steps S101 to S104.

In step S101, a first state of charge SOC1 of the battery is estimated by using a first state of charge estimation algorithm.

In step S102, a second state of charge SOC2 of the battery is estimate by using a second state of charge estimation algorithm.

In step S103, a first weight α corresponding to the first state of charge SOC1 and a second weight β corresponding to the second state of charge SOC2 are determined based on state data of the battery.

In step S104, the state of charge of the battery is calculated based on the first state of charge SOC1 and the first weight α, and the second state of charge SOC2 and the second weight β.

Hereinafter, steps 101 to 104 are described in detail.

According to an embodiment of the present disclosure, in step 101, the first state of charge estimation algorithm may be, for example, an open circuit voltage algorithm or an algorithm based on a battery equivalent circuit model.

According to the open circuit voltage algorithm, a state of charge of a battery is determined based on an open circuit voltage (OCV) of the battery. Taking a lithium-ion single cell battery as an example, the open circuit voltage of the battery when fully charged is generally about 4.2V, the open circuit voltage of the battery when fully discharged is about 2.6V. In charging and discharging the battery, the open circuit voltage of the battery constantly changes. It is found that there is a correlation relationship between open circuit voltage of a battery and states of charge of the battery. According to the correlation relationship, a state of charge of a battery may be calculated by performing data fitting based on an open circuit voltage of the battery. The advantage of using the open-circuit voltage algorithm as the first state of charge estimation algorithm is that the calculation amount of estimating the state of charge may be reduced, thereby improving the calculation speed in a certain accuracy range. However, as mentioned above, due to, for example, the polarization effect in lithium-ion batteries, the open circuit voltage of the battery, in a time period after stopping charging and discharging, is not constant but slowly changes. Usually, a voltage measured after the battery being left standing for a time period is an actual open circuit voltage of the battery under a current state of charge. In addition, for example, the correlation relationship between the open circuit voltages and the states of charge of lithium-ion batteries is greatly affected by environmental temperature, so that it is required to correct the first state of charge of the battery estimated by using the open circuit voltage algorithm. Since the open circuit voltage algorithm is known to those skilled in the art, for the sake of brevity, the open circuit voltage algorithm is not described in detail in the present disclosure.

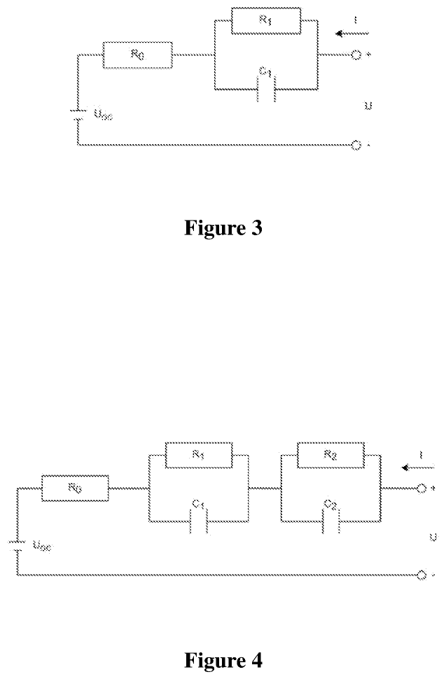

In addition, based on a battery equivalent circuit model-based algorithm, circuit components are used to physically model a battery to simulate electrical features of the battery. According to an embodiment of the present disclosure, the first state of charge estimation algorithm is a battery equivalent circuit model-based algorithm based on at least one of an R-int equivalent circuit model of the battery, a first-order RC equivalent circuit model (Thevenin model) of the battery, and a second-order RC equivalent circuit model of the battery. Referring to FIGS. 2 to 4, FIG. 2 is a circuit diagram showing an R-int equivalent circuit model of a battery, FIG. 3 is a circuit diagram showing a first-order RC equivalent circuit model of a battery, and FIG. 4 is a circuit diagram showing a second-order RC equivalent circuit model of a battery. In FIGS. 2 to 4, UOC represents a voltage source, and represents an open circuit voltage of a battery; R0, R1 and R2 represent resistors; C1 and C2 represent capacitors; and U and I respectively represent a voltage and a current of the battery. Since the battery equivalent circuit models are known to those skilled in the art, for the sake of brevity, the battery equivalent circuit models are not described in detail in the present disclosure.

With an equivalent circuit model, a state of charge of a battery may be calculated. Specifically, compared to the R-int equivalent circuit model, the first-order RC equivalent circuit model and the second-order RC equivalent circuit model have more parameters, so that it is difficult to solve. However, although the R-int equivalent circuit model is relatively simple, few cases are considered, and the accuracy of calculating the state of charge of the battery is low in a case that changes occur inside the battery. Therefore, further correction is still required.

According to an embodiment of the present disclosure, in step S101, a state of charge model of the battery may be established based on historical charging and discharging data of the battery, current charging and discharging data of the battery may be sensed, and the first state of charge SOC1 may be estimated by using the state of charge model based on the current charging and discharging data.

Specifically, according to an embodiment of the present disclosure, in step S101, a best charging and discharging curve may be automatically selected based on the historical charging and discharging data of the battery. Then, appropriate state data, such as a charging and discharging voltage, an equivalent internal resistance, and an estimated open circuit voltage, may be extracted based on the historical charging and discharging data and a rated charging and discharging cut-off voltage, and then the state of charge model of the battery is established based on the state data. According to an embodiment of the present disclosure, the state of charge model may be a charging and discharging curve fitted based on the historical charging and discharging data or a lookup table formed based on the historical charging and discharging data. Specifically, according to an embodiment of the present disclosure, the state of charge model may be a corresponding relationship between the historical charging and discharging data of the battery and the states of charge of the battery established by using the first state of charge estimation algorithm, such as the open circuit voltage algorithm or an algorithm based on a battery equivalent circuit model. In addition, according to an embodiment of the present disclosure, the historical charging and discharging data may include a current and/or a voltage of the battery.

According to an embodiment of the present disclosure, in step S101, after establishing the state of charge model of the battery, the battery may be energized to sense current charging and discharging data of the battery. Specifically, according to an embodiment of the present disclosure, the current charging and discharging data, such as a current and/or a voltage, of the battery may be sensed by using a sensor.

According to an embodiment of the present disclosure, in step S101, the first state of charge SOC1 may be estimated by using the established state of charge model based on the sensed current charging and discharging data. For example, in a case that the state of charge model of the battery is established as a lookup table, the first state of charge SOC1 may be obtained by querying the lookup table based on the sensed current charging and discharging data.

For example, according to an embodiment of the present disclosure, the first state of charge SOLI obtained in step S101 may be expressed by the following equation (1):

SOC1=f(U,I) (1)

where f represents the state of charge model established in step S101.

According to an embodiment of the present disclosure, in step S102 of the method 100, a second state of charge SOC 2 of the battery is estimated by using a second state of charge estimation algorithm. According to an embodiment of the present disclosure, the second state of charge estimation algorithm may be, for example, an ampere hour integration algorithm.

According to the ampere hour integration algorithm, a charging and discharging current of a battery is integrated with time, and then a charging state of the battery at a subsequent time instant is calculated based on an initial state of charge of the battery. Since the ampere hour integration algorithm is known to those skilled in the art, for the sake of brevity, the ampere hour integration algorithm is not described in detail in the present disclosure.

For example, according to an embodiment of the present disclosure, the second state of charge SOC2 obtained in step S102 may be expressed by the following equation (2):

SOC2=SOC0+(I*Δt)/C*100% (2)

where SOC0 represents an initial state of charge of the battery, ΔT represents an time interval with which a current I of the battery is integrated with time, and C represents a capacity of the battery based on an aging degree of the battery.

According to an embodiment of the present disclosure, in step 103 of the method 100, a first weight α corresponding to the first state of charge SOC1 and a second weight β corresponding to the second state of charge SOC2 are determined based on state data of the battery. According to an embodiment of the present disclosure, the first weight α corresponding to the first state of charge SOC1 may be used as a main weight, the second weight β corresponding to the second state of charge SOC2 may be used as a secondary weight, and when the battery operates in a certain state, the first state of charge SOC1 is corrected based on the second state of charge SOC2 by adjusting the first weight α and the second weight β.

According to an embodiment of the present disclosure, in step S103, a current state of the battery may be determined based on the historical charging and discharging data and the current charging and discharging data of the battery, and then the first weight α and the second weight β are determined based on the current state of the battery.

Specifically, according to an embodiment of the present disclosure, in step S103, in a case that the current state of the battery is determined as a quiescent state based on the historical charging and discharging data and the current charging and discharging data of the battery, the state of charge of the battery may be maintained unchanged.

In addition, according to an embodiment of the present disclosure, in step S103, the current state of the battery may be determined by: determining whether the battery enters a hysteresis state, and in a case that the battery enters the hysteresis state, determining a time period in which the battery operates in the hysteresis state.

In a battery, for example, a Lithium iron phosphate battery, a hysteresis feature exists. That is, a state of charge of the battery does not correspond to an open circuit voltage of the battery in charging and discharging the battery. Thus, in the embodiment in which the second state of charge SOC2 of the battery is estimated by using the ampere hour integration algorithm as the second state of charge estimation algorithm, a large error may exist in the estimated second state of charge SOC2 due to the hysteresis feature of the battery. Therefore, in step S103, the error may be corrected by adjusting the first weight α corresponding to the first state of charge SOC1 and the second weight β corresponding to the second state of charge SOC2. Specifically, according to an embodiment of the present disclosure, the state of charge model of the battery established in step S101 may to some extent reflect the impact of the hysteresis feature of the battery on the state of charge of the battery. Therefore, correction may be performed based on the first state of charge SOC1 determined in step S101 and the second state of charge SOC2.

Specifically, according to an embodiment of the present disclosure, in step S103, in a case that the current state of the battery is determined as an operation state based on the historical charging and discharging data and the current charging and discharging data of the battery, it may be determined whether the battery enters a hysteresis state. According to an embodiment of the present disclosure, in a case that the battery does not enter the hysteresis state, the first weight α and the second weight β may be maintained unchanged.

In addition, according to an embodiment of the present disclosure, in a case that the battery enters the hysteresis state, the first weight α is reduced and/or the second weight β is increased. In addition, according to an embodiment of the present disclosure, in a case that the battery enters the hysteresis state, a time period in which the battery operates in the hysteresis state may be further determined based on the historical charging and discharging data and the current charging and discharging data of the battery, and the first weight α and the second weight β may be gradually adjusted based on the time period in which the battery operates in the hysteresis state. For example, according to an embodiment of the present disclosure, in a case that the battery gradually switches from an operation state (the hysteresis state) to a quiescent state, the first weight α may be gradually increased and/or the second weight β may be reduced until the battery enters the quiescent state from the hysteresis state.

According to an embodiment of the present disclosure, in step 104 of the method 100, the state of charge of the battery may be calculated based on the first state of charge SOC1 and the first weight α, and the second state of charge SOC2 and the second weight β. Specifically, according to an embodiment of the present disclosure, the state of charge of the battery may be calculated by using the following equation (3):

(α*SOC1+β*SOC2)/(α+β) (3)

According to an embodiment of the present disclosure, the method 100 may further include: determining whether the battery operates in a dangerous stage based on the calculated state of charge of the battery and the current charging and discharging data (such as a voltage and/or a current) of the battery, and then issuing a safety or warning report.

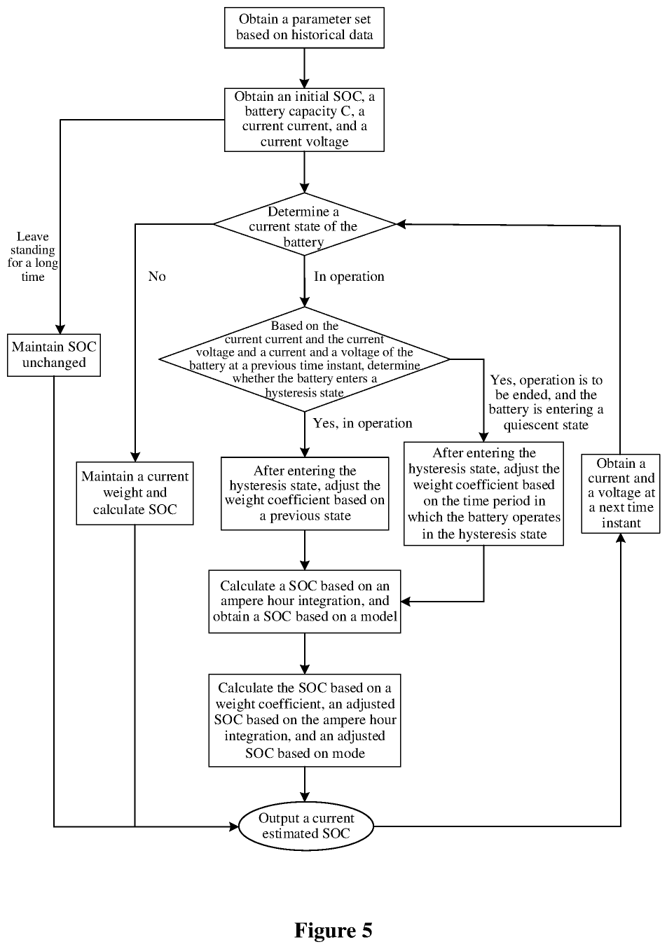

Hereinafter, in conjunction with an example shown in FIG. 5, an exemplary description is provided for the method 100 described above with reference to FIG. 1. FIG. is a flow chart showing an example of a method for calculating a state of charge of a battery according to an embodiment of the present disclosure.

As shown in FIG. 5, in step S101 of the method 100 described above with reference to FIG. 1, a parameter set of the battery is obtained based on historical charging and discharging data of the battery. The parameter set may be a state of charge model of the battery, such as a charging and discharging curve fitted based on the historical charging and discharging data or a lookup table formed based on the historical charging and discharging data. Subsequently, as shown in FIG. 5, the battery is powered on to obtain an initial state of charge, a capacity of the battery, and current charging and discharging data of the battery such as a current current and a current voltage of the battery.

Then, as shown in FIG. 5, as the step S103 of the method 100 described above with reference to FIG. 1, a current state of the battery is determined. In a case that the current state of the battery is determined as a quiescent state, that is, it is determined that the battery is left standing for a long time, the state of charge of the battery is maintained unchanged.

In addition, as shown in FIG. 5, in a case that the current state of the battery is determined as an operation state, it is determined whether the battery enters a hysteresis state based on a current current and a current voltage of the battery (that is, current charging and discharging data of the battery) and a current and a voltage of the battery at a previous time instant (that is, historical charging and discharging data of the battery).

Then, as shown in FIG. 5, as the step S103 of the method 100 described above with reference to FIG. 1, in a case that the battery does not enter the hysteresis state, the current weight, that is the first weight α, may be maintained unchanged, the second weight β may be reduced, and then the state of charge of the battery is calculated.

In addition, as shown in FIG. 5, in a case that the battery enters the hysteresis state, the weight coefficient, that is, the first weight α and the second weight β, may be adjusted based on a previous state of the battery, that is, based on a current and a voltage of the battery at a previous time instant. In addition, as shown in FIG. 5, in the case that the battery enters the hysteresis state, a time period in which the battery operates in the hysteresis state may be further determined based on the historical charging and discharging data and the current charging and discharging data of the battery, and the first weight α and/or the second weight β may be gradually adjusted based on the time period in which the battery operates in the hysteresis state. For example, in a case that the battery gradually switches from an operation state (the hysteresis state) to a quiescent state, the first weight α may be gradually increased and/or the second weight β may be gradually reduced.

Then, as shown in FIG. 5, as the step S102 of the method 100 described above with reference to FIG. 1, a second state of charge of the battery is calculated by using a second state of charge estimation algorithm, such as an ampere hour integration algorithm. A first state of charge of the battery is obtained by using the previously established state of charge model of the battery.

Then, as shown in FIG. 5, as the step S104 of the method 100 described above with reference to FIG. 1, the state of charge of the battery is calculated based on the first state of charge and the first weight, and the second state of charge and the second weight. Then, the calculated state of charge of the battery may be outputted.

As shown in FIG. 5, steps after determining the current state of the battery as described above may be performed cyclically with a predetermined time interval. Based on charging and discharging data, such as a current and a voltage, of the battery obtained at a next time instant, the above cycle is performed continuously.

As an example, the method for calculating a state of charge of a battery according to the present disclosure is performed with historical data of a power station in a time period as a parameter extraction set and a testing set, an error of a final calculated state of charge of the battery may be less than 5% after a time period of adaptation. Specifically, an average error of the state of charge of the battery is −2.265, and a mean squared error is 9.673. For comparison, if the state of charge of the battery is calculated by using the ampere hour integration algorithm with the same parameter extraction set and the same testing set, an average error of the calculated state of charge of the battery is −3.212, and a mean squared error is 17.544. Obviously, the calculation accuracy of the method for calculating a state of charge of a battery according to the present disclosure is superior to the calculation accuracy of the ampere hour integration algorithm.

With the method for calculating a state of charge of a battery according to the present disclosure, a state of charge model of the battery may be established (such as, extracting a voltage-charge curve of the battery) by using a first state of charge estimation algorithm (such as, by using an R-int equivalent circuit model) based on changes in charging and discharging data (such as a current and a voltage) of the battery. In addition, the state of charge obtained by using the first state of charge estimation algorithm may be corrected by using a second state of charge estimation algorithm (such as, an ampere hour integration algorithm) when an internal state of the battery changes. By performing adaptation, a ratio of a weight for the voltage-charge curve of the battery and a weight for the ampere hour integration algorithm may be adjusted. The calculated state of charge is corrected based on the changes in current under different conditions, thereby obtaining an accurate state of charge of the battery.

Compared with the conventional open circuit voltage algorithm, with the method for calculating a state of charge of a battery according to the present disclosure, the time-consuming static experiment for measuring a relationship between charge states and open circuit voltages can be eliminated, and the problem of inaccurate calculation of an open circuit voltage caused by sudden and drastic changes in a current of the battery can be solved. In addition, compared with the ampere hour integration algorithm, with the method for calculating a state of charge of a battery according to the present disclosure, a cumulative error caused by long-term use of the ampere hour integration algorithm can be eliminated.

In addition, compared with the Kalman filter, with the method for calculating a state of charge of a battery according to the present disclosure, the lag of error prediction when sudden changes occur and disappear and the fluctuation in a state state can be eliminated.

Although the present disclosure has been disclosed based on the descriptions of specific embodiments of the present disclosure, it should be understood that those skilled in the art may design various modifications, improvements, or equivalents to the present disclosure within the spirit and scope of the attached claims. These modifications, improvements, or equivalents should fall into the protection scope of the present disclosure.

1. A method for calculating a state of charge of a battery, comprising:
estimating a first state of charge of the battery by using a first state of charge estimation algorithm;
estimating a second state of charge of the battery by using a second state of charge estimation algorithm;
determining a first weight corresponding to the first state of charge and a second weight corresponding to the second state of charge based on state data of the battery; and
calculating the state of charge of the battery based on the first state of charge and the first weight, and the second state of charge and the second weight.

2. The method according to claim 1, wherein the first state of charge estimation algorithm is an open circuit voltage algorithm, and the second state of charge estimation algorithm is an ampere hour integration algorithm.

3. The method according to claim 1, wherein the first state of charge estimation algorithm is a battery equivalent circuit model-based algorithm based on at least one of an R-int equivalent circuit model of the battery, a first-order RC equivalent circuit model of the battery, and a second-order RC equivalent circuit model of the battery.

4. The method according to claim 2, wherein the estimating a first state of charge of the battery by using a first state of charge estimation algorithm comprises:
establishing a state of charge model of the battery based on historical charging and discharging data of the battery;
sensing current charging and discharging data of the battery; and
estimating the first state of charge by using the state of charge model based on the current charging and discharging data.

5. The method according to claim 4, wherein the state of charge model is a charging and discharging curve fitted based on the historical charging and discharging data or a lookup table formed based on the historical charging and discharging data.

6. The method according to claim 4, wherein the historical charging and discharging data and the current charging and discharging data comprise a current and/or a voltage of the battery.

7. The method according to claim 4, wherein the determining a first weight corresponding to the first state of charge and a second weight corresponding to the second state of charge based on state data of the battery comprises:
determining a current state of the battery based on the historical charging and discharging data and the current charging and discharging data; and
determining the first weight and the second weight based on the current state.

8. The method according to claim 7, wherein the determining a current state comprises:
determining whether the battery enters a hysteresis state; and
in a case that the battery enters the hysteresis state, determining a time period in which the battery operates in the hysteresis state.

9. The method according to claim 8, wherein the determining the first weight and the second weight based on the current state comprises:
in the case that the battery enters the hysteresis state, reducing the first weight and/or increasing the second weight; and
gradually adjusting the first weight and/or increasing the second weight based on the time period in which the battery operates in the hysteresis state.

10. The method according to claim 3, wherein the estimating a first state of charge of the battery by using a first state of charge estimation algorithm comprises:
establishing a state of charge model of the battery based on historical charging and discharging data of the battery;
sensing current charging and discharging data of the battery; and
estimating the first state of charge by using the state of charge model based on the current charging and discharging data.

11. The method according to claim 10, wherein the state of charge model is a charging and discharging curve fitted based on the historical charging and discharging data or a lookup table formed based on the historical charging and discharging data.

12. The method according to claim 10, wherein the historical charging and discharging data and the current charging and discharging data comprise a current and/or a voltage of the battery.

13. The method according to claim 10, wherein the determining a first weight corresponding to the first state of charge and a second weight corresponding to the second state of charge based on state data of the battery comprises:
determining a current state of the battery based on the historical charging and discharging data and the current charging and discharging data; and
determining the first weight and the second weight based on the current state.

14. The method according to claim 13, wherein the determining a current state comprises:
determining whether the battery enters a hysteresis state; and
in a case that the battery enters the hysteresis state, determining a time period in which the battery operates in the hysteresis state.

15. The method according to claim 14, wherein the determining the first weight and the second weight based on the current state comprises:
in the case that the battery enters the hysteresis state, reducing the first weight and/or increasing the second weight; and
gradually adjusting the first weight and/or increasing the second weight based on the time period in which the battery operates in the hysteresis state.

16. The method according to claim 1, wherein the battery is a lithium ion battery or a Sodium-ion battery.
